(19) United States
(12) Patent Application Publication
(10) Pub. No.: US 2013/0093099 A1
(43) Pub. Date: Apr. 18, 2013

(54) SEMICONDUCTOR APPARATUS

(71) Applicants: Sang Hoon SHIN, Ichon-shi (KR); Dong Uk LEE, Ichon-shi (KR)

(72) Inventors: Sang Hoon SHIN, Ichon-shi (KR); Dong Uk LEE, Ichon-shi (KR)

(73) Assignee: HYNIX SEMICONDUCTOR INC., Ichon-si (KR)

(21) Appl. No.: 13/445,676

(22) Filed: Apr. 12, 2012

(30) Foreign Application Priority Data
Oct. 18, 2011 (KR) 10-2011-0106161

(51) Int. Cl. H01L 23/48

(52) U.S. Cl. 257/774; 257/E23.011

(57) ABSTRACT

A semiconductor apparatus having first and second chips stacked upon each other includes first, second and third through vias positioned on a same vertical lines in the first and second chips and formed through the first and second chips. A first input/output circuit connected with the second through via of the first chip. A second input/output circuit connected with the second through via of the second chip. The second through via of the second chip is connected with the first through via of the first chip.

### CROSS-REFERENCES TO RELATED APPLICATION

The present application claims priority under 35 U.S.C. §119(a) to Korean application number 10-2011-0106161, filed on Oct. 18, 2011, in the Korean Intellectual Property Office, which is incorporated herein by reference in its entirety as set forth in full.

### BACKGROUND

1. Technical Field

The present invention relates to a semiconductor apparatus, and more particularly, to a 3D (three-dimensional) semiconductor apparatus using through vias.

2. Related Art

In order to improve the degree of integration of a semiconductor apparatus, a 3D (three-dimensional) semiconductor apparatus has been developed. The 3D semiconductor apparatus typically includes a plurality of chips that are stacked and packaged to increase the degree of integration. In the 3D semiconductor apparatus, since two or more chips are vertically stacked, a maximum degree of integration may be achieved in a same area.

Recently, a TSV (through-silicon via) type semiconductor apparatus has been disclosed in the art, in which through-silicon vias are formed to pass through a plurality of stacked chips so that all the chips are electrically connected with one another. In the TSV type semiconductor apparatus, because the through-silicon vias vertically pass through respective chips to electrically connect the respective chips with one another, the size of a package may be efficiently reduced when compared to a semiconductor apparatus in which respective chips are connected with one another through peripheral wiring.

FIG. 1 is a view schematically illustrating a configuration of a conventional semiconductor apparatus. In FIG. 1, four chips are stacked to constitute a semiconductor apparatus. First to fourth chips CHIP0 to CHIP3 are electrically connected with one another through first to fourth through vias 11 to 14, 21 to 24, 31 to 34 and 41 to 44. The first through vias 11, 21, 31 and 41 of the first to fourth chips CHIP0 to CHIP3 are positioned on a same vertical line and electrically connect the first to fourth chips CHIP0 to CHIP3 with is one another, and the second through vias 12, 22, 32 and 42 of the first to fourth chips CHIP0 to CHIP3 are positioned on a same vertical line and electrically connect the first to fourth chips CHIP0 to CHIP3 with one another. Similarly, the third and fourth through vias 13, 23, 33, 43, 14, 24, 34 and 44 of the first to fourth chips CHIP0 to CHIP3 are positioned on same vertical lines and electrically connect the first to fourth chips CHIP0 to CHIP3 with one another.

All the through vias 11 to 14, 21 to 24, 31 to 34 and 41 to 44, which are formed through the first to fourth chips CHIP0 to CHIP3, are respectively connected with input/output circuits 15 to 18, 25 to 28, 35 to 38 and 45 to 48. Activation (ON) and deactivation (OFF) of the respective input/output circuits 15 to 18, 25 to 28, 35 to 38 and 45 to 48 are determined by chip select signals CS0 to CS3. The first through vias 11, 21, 31 and 41 form a fourth channel CH3 and form a communication path with the fourth chip CHIP3. The second through vias 12, 22, 32 and 42 form a third channel CH2 and form a communication path with the third chip CHIP2. The third through vias 13, 23, 33 and 43 form a second channel CH1 and form a communication path with the second chip CHIP1. The fourth through vias 14, 24, 34 and 44 form a first channel CH0 and form a communication path with the first chip CHIP0. In order to allow communication between the chips and the channels in these ways, in the first chip CHIP0, only the input/output circuit 18, which is connected with the fourth through via 14 of the first chip CHIP0, is activated (ON) in response to the first chip select signal CS0. In the second chip CHIP1, only the input/output circuit 27, which is connected with the third through via 23 of the second chip CHIP1, is activated (ON) in response to the second chip select signal CS1. Similarly, in the third and fourth chips CHIP2 and CHIP3, only the input/output circuit 36, which is connected with the second through via 32 of the third chip CHIP2, and the input/output circuit 45, which is connected with the first through via 41 of the fourth chip CHIP3, are activated (ON) in response to the third and fourth chip select signals CS2 and CS3.

In the conventional semiconductor apparatus, an independent channel is assigned to each of stacked chips, and each chip forms the channel through one input/output circuit. However, since the respective chips are manufactured to have a same structure according to a same process, they may include input/output circuits which are connected with all through vias formed in all chips. That is to say, as shown in FIG. 1, respective chips are manufactured to include the same number of input/output circuits as the number of all through vias formed in each chip, and after the chips are stacked, only one input/output circuit is activated in each chip according to a chip select signal so that an individual channel is formed. When the semiconductor apparatus actually operates, remaining input/output circuits excluding the one input/output circuit in each chip become unnecessary circuits, and the areas occupied by these unnecessary circuits adversely influence the high integration of a semiconductor apparatus.

### SUMMARY

A semiconductor apparatus which includes various connection structures of through vias formed in stacked chips is described herein.

In one embodiment of the present invention, a semiconductor apparatus having first and second chips stacked upon each other includes: first, second and third through vias positioned on same vertical lines in the first and second chips and formed through the first and second chips; a first input/output circuit connected with the second through via of the first chip; and a second input/output circuit connected with the second through via of the second chip, wherein the second through via of the second chip is connected with the first through via of the first chip.

In another embodiment of the present invention, a semiconductor apparatus having first to n^{th} chips (n is an integer equal to or greater than 3) stacked upon one another includes: first to m^{th} (m is an integer greater than n) through vias positioned on same vertical lines in the first to n^{th} chips and formed through the first to n^{th} chips; and input/output circuits respectively connected with n*k^{th} (k is a natural number) through vias of the first to n^{th} chips, wherein the n^{th} through via of the n^{th} chip is connected with the n−1^{th} through via of the n−1^{th} chip, and the n^{th} through via of the n−1^{th} chip is connected with the n+1^{th} through via of the n^{th} chip and the n−1^{th} through via of the n−2^{th} chip.

In another embodiment of the present invention, a semiconductor apparatus having first to fourth chips sequentially stacked upon one another, the first and second chips constituting a first rank and the third and fourth chips constituting a second rank includes: first to fourth through vias positioned on the same vertical lines in the first to fourth chips and formed through the first to fourth chips; input/output circuits connected with the second through vias of the first to fourth chips; and input/output circuits connected with the fourth through vias of the first to fourth chips, wherein the fourth through via of the fourth chip is connected sequentially with the third through via of the third chip, the second through via of the second chip and the first through via of the first chip, and forms a first channel.

In another embodiment of the present invention, a semiconductor apparatus having first to fourth chips sequentially stacked upon one another, the first and second chips constituting a first rank and the third and fourth chips constituting a second rank includes: first to third through vias positioned on the same vertical lines in the first to fourth chips and formed through the first to fourth chips; and input/output circuits connected with the second through vias of the first to fourth chips, wherein the second through via of the fourth chip is connected sequentially with the first through via of the third chip, the second through via of the second chip and the first through via of the first chip, and forms a first channel.

### BRIEF DESCRIPTION OF THE DRAWINGS

Features, aspects, and embodiments are described in conjunction with the attached drawings, in which:

FIG. 1 is a view schematically illustrating a configuration of a conventional semiconductor apparatus;

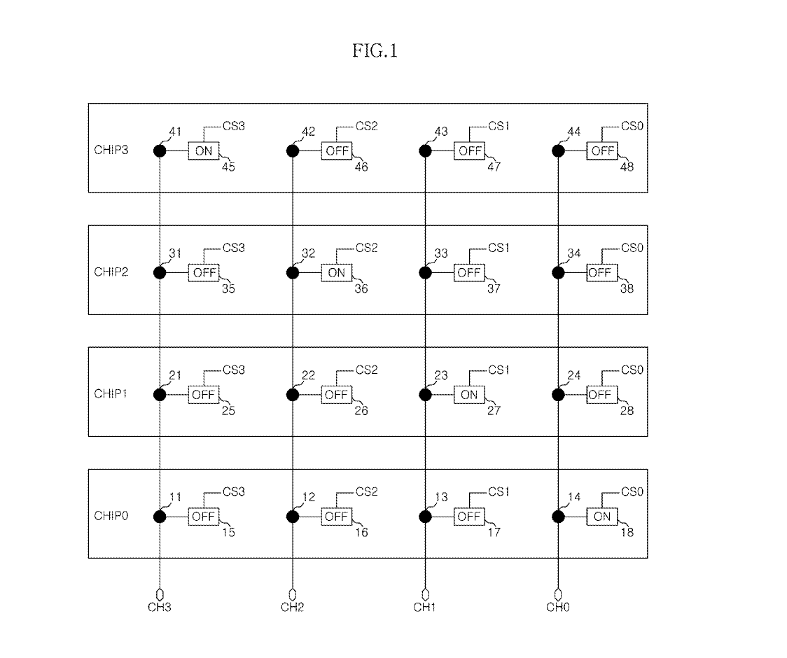

FIG. 2 is a view illustrating a configuration of a semiconductor apparatus in accordance with an embodiment of the present invention;

FIG. 3 is a view illustrating a configuration of a semiconductor apparatus in accordance with an embodiment to which a technical concept of the semiconductor apparatus shown in FIG. 2 is applied;

FIG. 4 is a view illustrating a configuration of a semiconductor apparatus in accordance with another embodiment of the present invention;

FIG. 5 is a view illustrating a configuration of a semiconductor apparatus in accordance with an embodiment to which a technical concept of the semiconductor apparatus shown in FIG. 4 is applied;

FIG. 6 is a view illustrating a configuration of a semiconductor apparatus in accordance with still another embodiment of the present invention;

FIG. 7 is a view illustrating a configuration of a semiconductor apparatus in accordance with an embodiment to which a technical concept of the semiconductor apparatus shown in FIG. 6 is applied; and

FIG. 8 is a view schematically illustrating a through via connection scheme that may be adopted in a semiconductor apparatus in accordance with embodiments of the present invention.

### DETAILED DESCRIPTION

Hereinafter, a semiconductor apparatus according to the present invention will be described below with reference to the accompanying drawings through example embodiments.

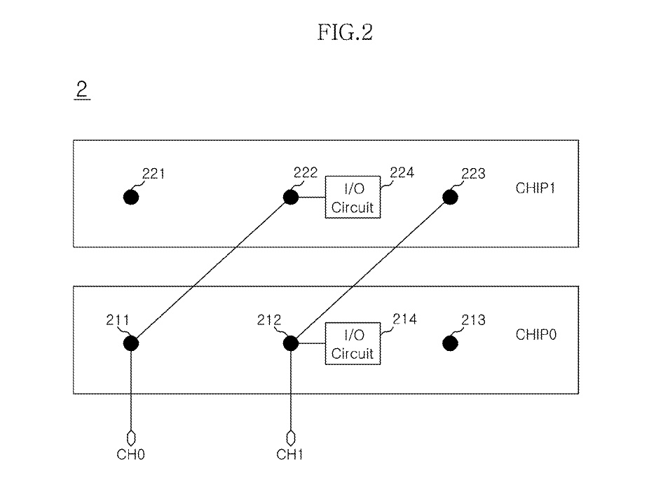

FIG. 2 is a view illustrating a configuration of a semiconductor apparatus 2 in accordance with an embodiment of the present invention. In FIG. 2, the semiconductor apparatus 2 includes a first chip CHIP0 and a second chip CHIP1. The first and second chips CHIP0 and CHIP1 are stacked to constitute the semiconductor apparatus 2. The first chip CHIP0 includes first and second through vias 211 and 212 which are formed through the first chip CHIP0. The second chip CHIP1 includes first and second through vias 221 and 222 which are formed through the second chip CHIP1. The first through via 211 of the first chip CHIP0 and the first through via 221 of the second CHIP1 are positioned on a same vertical line. The second through via 212 of the first chip CHIP0 and the second through via 222 of the second CHIP1 are also positioned on a same vertical line. In the present embodiment, through vias are formed through disposed chips and are illustrated as black circles for the sake of clear and concise explanations.

The through vias 212 and 222 of the first and second chips CHIP0 and CHIP1 are respectively connected with input/output circuits 214 and 224. The input/output circuits 214 and 224 are circuits which perform communications between the first and second chips CHIP0 and CHIP1 and channels. The input/output circuits 214 and 224 include, but are not limited to, circuits for inputting/outputting data, address signals or command signals.

The second through via 222 of the second chip CHIP1 is connected with the first through via 211 of the first chip CHIP0 and forms a first channel CH0. The second through via 212 of the first chip CHIP0 forms a second channel CH1. Accordingly, the input/output circuit 224 connected with the second through via 222 of the second chip CHIP1 is connected with the first channel CH0, and the input/output circuit 214 connected with the second through via 212 of the first chip CHIP0 is connected with the second channel CH1. Through this configuration, a plurality of chips constituting the semiconductor apparatus 2 may be allocated with different channels, respectively. That is to say, the first chip CHIP0 may communicate with the second channel CH1 by the medium of the input/output circuit 214, and the second chip CHIP1 may communicate with the first channel CH0 by the medium of the input/output circuit 224.

In FIG. 2, the first and second chips CHIP0 and CHIP1 further include third through vias 213 and 223 which are positioned on the same vertical line and are formed through the first and second chips CHIP0 and CHIP1. The third through via 223 of the second chip CHIP1 may be connected with the second through via 212 of the first chip CHIP0. Meanwhile, the first through via 221 of the second chip CHIP1 and the third through via 213 of the first chip CHIP0 may be unconnected with other component elements.

The semiconductor apparatus 2 in accordance with an embodiment of the present invention renders an improved connection structure of through vias and provides advantages in terms of chip area. In other words, by using additional through vias when compared to the conventional art, the configuration of input/output circuits connected with all through vias may be replaced. As can be readily seen from FIG. 2, because the semiconductor apparatus 2 has the input/output circuits 214 and 224 connected with the second through vias 212 and 222 of the first and second chips CHIP0 and CHIP1, different channels may be allocated to the respective first and second chips CHIP0 and CHIP1.

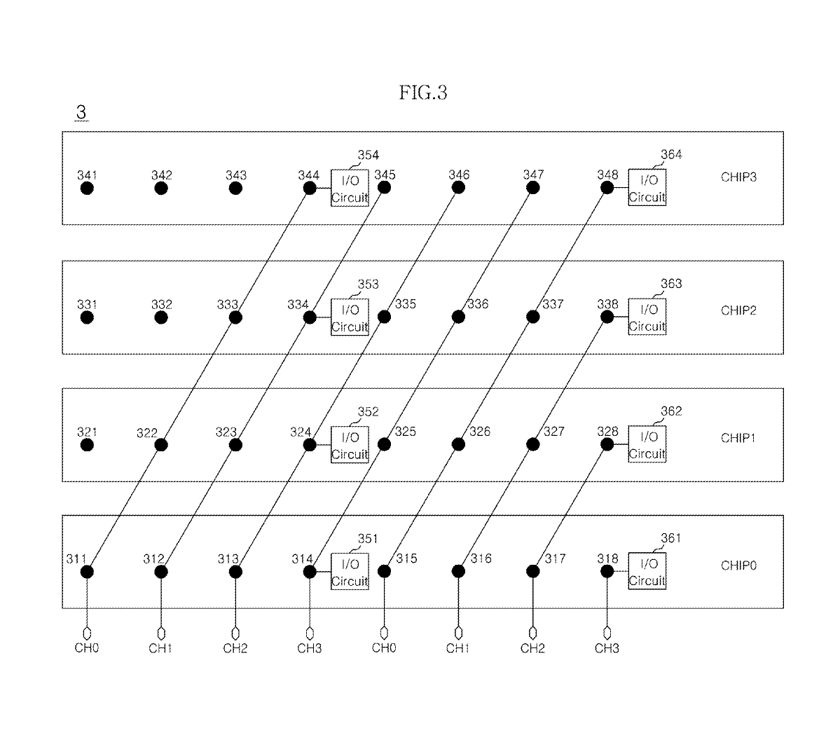

FIG. 3 is a view illustrating a configuration of a semiconductor apparatus 3 in accordance with an embodiment to which the technical concept of the semiconductor apparatus 2 shown in FIG. 2 is applied.

In FIG. 3, the semiconductor apparatus 3 includes first to fourth chips CHIP0 to CHIP3. The first to fourth chips CHIP0 to CHIP3 are sequentially stacked and constitute the semiconductor apparatus 3. The first to fourth chips CHIP0 to CHIP3 include first to fourth through vias 311 to 314, 321 to 324, 331 to 334 and 341 to 344 which are positioned on the same vertical lines and are formed through the first to fourth chips CHIP0 to CHIP3. The fourth through vias 314, 324, 334 and 344 of the first to fourth chips CHIP0 to CHIP3 are respectively connected with input/output circuits 351, 352, 353 and 354.

The fourth through via 344 of the fourth chip CHIP3 is connected sequentially with the third through via 333 of the third chip CHIP2, the second through via 322 of the second chip CHIP1 and the first through via 311 of the first chip CHIP0, and forms a first channel CH0. Accordingly, the fourth chip CHIP3 may communicate with the first channel CH0 by the medium of the input/output circuit 354 which is connected with the fourth through via 344 of the fourth chip CHIP3.

The fourth through via 334 of the third chip CHIP2 is connected sequentially with the third through via 323 of the second chip CHIP1 and the second through via 312 of the first chip CHIP0, and forms a second channel CH1. Accordingly, the third chip CHIP2 may communicate with the second channel CH1 by the medium of the input/output circuit 353 which is connected with the fourth through via 334 of the third chip CHIP2.

The fourth through via 324 of the second chip CHIP1 is connected with the third through via 313 of the first chip CHIP0 and forms a third channel CH2. Accordingly, the second chip CHIP1 may communicate with the third channel CH2 by the medium of the input/output circuit 352 which is connected with the fourth through via 324 of the second chip CHIP1.

The fourth through via 314 of the first chip CHIP0 forms a fourth channel CH3. The first chip CHIP0 may communicate with the fourth channel CH3 by the medium of the input/output circuit 351 which is connected with the fourth through via 314 of the first chip CHIP0.

The first through via 321 of the second chip CHIP1, the first and second through vias 331 and 332 of the third chip CHIP2, and the first to third through vias 341 to 343 of the fourth chip CHIP3 may not form any connections.

In FIG. 3, the first to fourth chips CHIP0 to CHIP3 further include fifth to eighth through vias 315 to 318, 325 to 328, 335 to 338 and 345 to 348 which are positioned on the same vertical lines and are formed through the first to fourth chips CHIP0 to CHIP3. The eighth through vias 318, 328, 338 and 348 of the first to fourth chips CHIP0 to CHIP3 are respectively connected with input/output circuits 361, 362, 363 and 364.

The eighth through via 348 of the fourth chip CHIP3 is connected sequentially with the seventh through via 337 of the third chip CHIP2, the sixth through via 326 of the second chip CHIP1 and the fifth through via 315 of the first chip CHIP0, and forms the first channel CH0. The eighth through via 338 of the third chip CHIP2 is connected sequentially with the seventh through via 327 of the second chip CHIP1 and the sixth through via 316 of the first chip CHIP0, and forms the second channel CH1. The eighth through via 328 of the second chip CHIP1 is connected with the seventh through via 317 of the first chip CHIP0 and forms the third channel CH2. The eighth through via 318 of the first chip CHIP0 forms the fourth channel CH3. Meanwhile, the fourth through via 334 of the third chip CHIP2 may be connected with the fifth through via 345 of the fourth chip CHIP3. The fourth through via 324 of the second chip CHIP1 may be connected sequentially with fifth through via 335 of the third chip CHIP2 and the sixth through via 346 of the fourth chip CHIP3. The fourth through via 314 of the first chip CHIP0 may be connected sequentially with the fifth through via 325 of the second chip CHIP1, the sixth through via 336 of the third chip CHIP2 and the seventh through via 347 of the fourth chip CHIP3.

While not shown in FIG. 3, the eighth through via 338 of the third chip CHIP2 may be connected with a ninth through via of the fourth chip CHIP3, and the eighth through via 328 of the second chip CHIP1 may be connected with a ninth through via of the third chip CHIP2 and a tenth through via of the fourth chip CHIP3. The eighth through via 318 of the first chip CHIP0 may be connected with a ninth through via of the second chip CHIP1, a tenth through via of the third chip CHIP2 and an eleventh through via of the fourth chip CHIP3.

Therefore, in the semiconductor apparatus 3 in accordance with an embodiment of the present invention, when compared to the conventional art, since only eight input/output circuits are needed while the numbers of through vias formed in respective chips are slightly increased in order to form fourth pairs of channels which communicate with fourth chips, a circuit area may be significantly reduced.

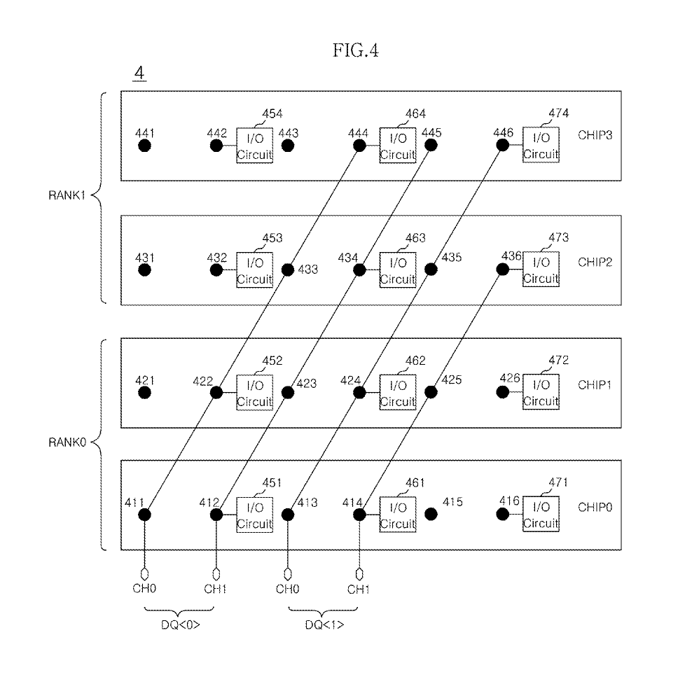

FIG. 4 is a view illustrating the configuration of a semiconductor apparatus 4 in accordance with another embodiment of the present invention.

In FIG. 4, the semiconductor apparatus 4 includes first to fourth chips CHIP0 to CHIP3. The first to fourth chips CHIP0 to CHIP3 are sequentially stacked to constitute a single semiconductor apparatus 4. The first to fourth chips CHIP0 to CHIP3 include first to fourth through vias 411 to 414, 421 to 424, 431 to 434 and 441 to 444 which are positioned on the same vertical lines and are formed through the first to fourth chips CHIP0 to CHIP3. The second through vias 412, 422, 432 and 442 of the first to fourth chips CHIP0 to CHIP3 are respectively connected with input/output circuits 451, 452, 453 and 454. The fourth through vias 414, 424, 434 and 444 of the first to fourth chips CHIP0 to CHIP3 are respectively connected with input/output circuits 461, 462, 463 and 464.

Meanwhile, the first and second chips CHIP0 and CHIP1 constitute a first rank RANK0, and the third and fourth chips CHIP2 and CHIP3 constitute a second rank RANK1.

The fourth through via 444 of the fourth chip CHIP3 is connected sequentially with the third through via 433 of the third chip CHIP2, the second through via 422 of the second chip CHIP1 and the first through via 411 of the first chip CHIP0, and forms a first channel CH0. The fourth chip CHIP3 may communicate with the first channel CH0 by the medium of the input/output circuit 464 which is connected with the fourth through via 444 of the fourth chip CHIP3 and the input/output circuit 452 which is connected with the second through via 422 of the second chip CHIP1.

The fourth through via 434 of the third chip CHIP3 is connected sequentially with the third through via 423 of the second chip CHIP1 and the second through via 412 of the first chip CHIP0, and forms a second channel CH1. The third chip CHIP2 may communicate with the second channel CH1 by the medium of the input/output circuit 463 which is connected with the fourth through via 434 of the third chip CHIP2 and the input/output circuit 451 which is connected with the second through via 412 of the first chip CHIP0.

The semiconductor apparatus 4 may further include fifth and sixth through vias 415 and 416, 425 and 426, 435 and 436 and 445 and 446 which are positioned on the same vertical line and are formed through the first to fourth chips CHIP0 to CHIP3. The sixth through vias 416, 426, 436 and 446 of the first to fourth chips CHIP0 to CHIP3 are respectively connected with input/output circuits 471, 472, 473 and 474.

The sixth through via 446 of the fourth chip CHIP3 is connected sequentially with the fifth through via 435 of the third chip CHIP2, the fourth through via 424 of the second chip CHIP1 and the third through via 413 of the first chip CHIP0, and forms the first channel CH0. Accordingly, the fourth chip CHIP3 may communicate with the first channel CH0 by the medium of the input/output circuit 474 which is connected with the sixth through via 446 of the fourth chip CHIP3 and the input/output circuit 462 which is connected with the fourth through via 424 of the second chip CHIP1.

The sixth through via 436 of the third chip CHIP2 is connected with the fifth through via 425 of the second chip CHIP1 and the fourth through via 414 of the first chip CHIP0, and forms the second channel CH1. Accordingly, the third chip CHIP2 may communicate with the second channel CH1 by the medium of the input/output circuit 473 which is connected with the sixth through via 436 of the third chip CHIP2 and the input/output circuit 461 which is connected with the fourth through via 414 of the first chip CHIP0.

The input/output circuits 453 and 454, which are connected with the second through vias 432 and 442 of the third and fourth chips CHIP2 and CHIP3, may be deactivated in response to a first rank select signal which activates the first rank RANK0, and the input/output circuits 471 and 472, which are connected with the sixth through vias 416 and 426 of the first and second chips CHIP0 and CHIP1, may be deactivated in response to a second rank select signal which activates the second rank RANK1. In an embodiment of the present invention, it can be seen that the numbers of input/output circuits which are disposed in a plurality of chips may be minimized even when the plurality of chips constituting different ranks form a plurality of pairs of channels.

In an embodiment of the present invention, channels mean groups which independently use signals such as a command signal, an address signal and data, and ranks mean groups which share the signals such as a command signal, an address signal and data. Accordingly, the semiconductor apparatus may increase bandwidths by distinguishing channels and may improve densities by distinguishing ranks.

In FIG. 4, the first and third chips CHIP0 and CHIP2 are allocated with the second channel CH1 in the same manner, and the second and fourth chips CHIP1 and CHIP3 are allocated with the first channel CH0 in the same manner. Also, in the semiconductor apparatus 4, the first rank RANK0 and the second rank RANK1 are selectively activated in response to the first and second rank select signals. In other words, operations of the first and second chips CHIP0 and CHIP1 and operations of the third and fourth chips CHIP2 and CHIP3 are selectively performed. Further, since chips which belong to the same ranks are allocated with separate channels, they are controlled by different command signals, address signals and data. For example, when the first rank RANK0 is activated, the data stored in the first chip CHIP0 may be outputted through the second cannel CH1 by a predetermined command signal and address signal, and the data stored in the second chip CHIP1 may be outputted through the first channel CH0 by a command signal and address signal which are different from the predetermined command signal and address signal. Moreover, when the second rank RANK1 is activated, the data stored in the third chip CHIP2 may be outputted through the second cannel CH1 by the predetermined command signal and address signal, and the data stored in the fourth chip CHIP3 may be outputted through the first channel CH0 by the different command signal and address is signal.

The first and second channels CH0 and CH1 are determined as the same data group DQ when viewed from an outside of the semiconductor apparatus 4 (for example, a controller, etc.). In FIG. 4, the first channel CH0, which communicates with the input/output circuit 464 connected with the fourth through via 444 of the fourth chip CHIP3 and the input/output circuit 452 connected with the second through via 422 of the second chip CHIP1, and the second channel CH1, which communicates with the input/output circuit 463 connected with the fourth through via 434 of the third chip CHIP2 and the input/output circuit 451 connected with the second through via 412 of the first chip CHIP0, are determined as a first data group DQ<0>. Furthermore, the first channel CH0, which communicates with the input/output circuit 474 connected with the sixth through via 446 of the fourth chip CHIP3 and the input/output circuit 462 connected with the fourth through via 424 of the second chip CHIP1, and the second channel CH1, which communicates with the input/output circuit 473 connected with the sixth through via 436 of the third chip CHIP2 and the input/output circuit 461 connected with the fourth through via 414 of the first chip CHIP0, are determined as a second data group DQ<1>. These descriptions regarding channels and ranks may be applied to all semiconductor apparatuses in accordance with embodiments of the present invention which are described above or will be described later.

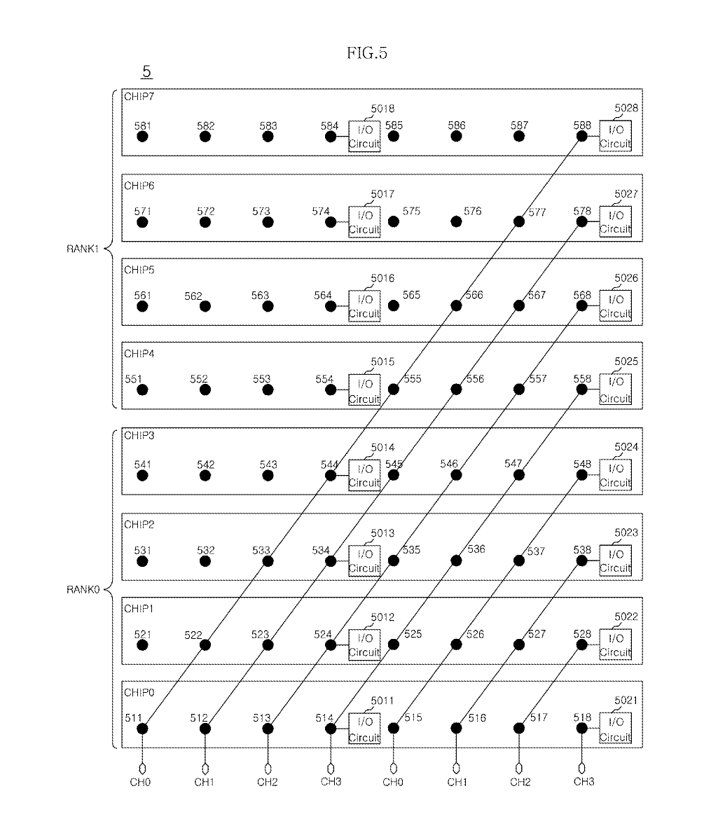

FIG. 5 is a view illustrating the configuration of a is semiconductor apparatus 5 in accordance with an embodiment to which the technical concept of the semiconductor apparatus 4 shown in FIG. 4 is applied. In FIG. 5, the semiconductor apparatus 5 includes first to eighth chips CHIP0 to CHIP7. The first to eighth chips CHIP0 to CHIP7 are sequentially stacked and constitute the single semiconductor apparatus 5. The first to eighth chips CHIP0 to CHIP7 include first to eighth through vias 511 to 518, 521 to 528, 531 to 538, 541 to 548, 551 to 558, 561 to 568, 571 to 578 and 581 to 588 which are positioned on the same vertical lines and are formed through the first to eighth chips CHIP0 to CHIP7. The fourth through vias 514, 524, 534, 544, 554, 564, 574 and 584 of the first to eighth chips CHIP0 to CHIP7 are respectively connected with input/output circuits 5011, 5012, 5013, 5014, 5015, 5016, 5017 and 5018, and the eighth through vias 518, 528, 538, 548, 558, 568, 578 and 588 of the first to eighth chips CHIP0 to CHIP7 are respectively connected with input/output circuits 5021, 5022, 5023, 5024, 5025, 5026, 5027 and 5028. The first to fourth chips CHIP0 to CHIP3 constitute a first rank RANK0, and the fifth to eighth chips CHIP4 to CHIP7 constitute a second rank RANK1.

The eighth through via 588 of the eighth chip CHIP7 is connected sequentially with the seventh through via 577 of the seventh chip CHIP6, the sixth through via 566 of the sixth chip CHIP5, the fifth through via 555 of the fifth chip CHIP4, the fourth through via 544 of the fourth chip CHIP3, the third through via 533 of the third chip CHIP2, the second through via 522 of the second chip CHIP1 and the first through via 511 of the first chip CHIP0, and forms a first channel CH0. Accordingly, the eighth chip CHIP7 may communicate with the first channel CH0 by the medium of the input/output circuit 5028 which is connected with the eighth through via 588 of the eighth chip CHIP7, and the fourth chip CHIP3 may communicate with the first channel CH0 by the medium of the input/output circuit 5014 which is connected with the fourth through via 544 of the fourth chip CHIP3.

The eighth through via 578 of the seventh chip CHIP6 is connected sequentially with the seventh through via 567 of the sixth chip CHIP5, the sixth through via 556 of the fifth chip CHIP4, the fifth through via 545 of the fourth chip CHIP3, the fourth through via 534 of the third chip CHIP2, the third through via 523 of the second chip CHIP1 and the second through via 512 of the first chip CHIP0, and forms a second channel CH1. Accordingly, the seventh chip CHIP6 may communicate with the second channel CH1 by the medium of the input/output circuit 5027 which is connected with the eighth through via 578 of the seventh chip CHIP6, and the third chip CHIP2 may communicate with the second channel CH1 by the medium of the input/output circuit 5013 which is connected with the fourth through via 534 of the third chip CHIP2.

The eighth through via 568 of the sixth chip CHIP5 is connected sequentially with the seventh through via 557 of the fifth chip CHIP4, the sixth through via 546 of the fourth chip CHIP3, the fifth through via 535 of the third chip CHIP2, the fourth through via 524 of the second chip CHIP1 and the third through via 513 of the first chip CHIP0, and forms a third channel CH2. Accordingly, the sixth chip CHIP5 may communicate with the third channel CH2 by the medium of the input/output circuit 5026 which is connected with the eighth through via 568 of the sixth chip CHIP5, and the second chip CHIP1 may communicate with the third channel CH2 by the medium of the input/output circuit 5012 which is connected with the fourth through via 524 of the second chip CHIP1.

The eighth through via 558 of the fifth chip CHIP4 is connected sequentially with the seventh through via 547 of the fourth chip CHIP3, the sixth through via 536 of the third chip CHIP2, the fifth through via 525 of the second chip CHIP1 and the fourth through via 514 of the first chip CHIP0, and forms a fourth channel CH3. Accordingly, the fifth chip CHIP4 may communicate with the fourth channel CH3 by the medium of the input/output circuit 5025 which is connected with the eighth through via 558 of the fifth chip CHIP4, and the first chip CHIP0 may communicate with the fourth channel CH3 by the medium of the input/output circuit 5011 which is connected with the fourth through via 514 of the first chip CHIP0.

While not shown in FIG. 5, the first to eighth chips CHIP0 to CHIP7 may further include ninth to twelfth through vias. The twelfth through vias of the first to eighth chips CHIP0 to CHIP7 are respectively connected with input/output circuits. The twelfth through via of the eighth chip CHIP7 is connected sequentially with the eleventh through via of the seventh chip CHIP6, the tenth through via of the sixth chip CHIP5, the ninth through via of the fifth chip CHIP4, the eighth through via 548 of the fourth chip CHIP3, the seventh through via 537 of the third chip CHIP2, the sixth through via 526 of the second chip CHIP1 and the fifth through via 515 of the first chip CHIP0, and forms the first channel CH0. Accordingly, the eighth chip CHIP7 may communicate with the first channel CH0 by the medium of the input/output circuit which is connected with the twelfth through via of the eighth chip, and the fourth chip CHIP3 may communicate with the first channel CH0 by the medium of the input/output circuit 5024 which is connected with the eighth through via 548 of the fourth chip CHIP3.

The twelfth through via of the seventh chip CHIP6 is connected sequentially with the eleventh through via of the sixth chip CHIP5, the tenth through via of the fifth chip CHIP4, the ninth through via of the fourth chip CHIP3, the eighth through via 538 of the third chip CHIP2, the seventh through via 527 of the second chip CHIP1 and the sixth through via 516 of the first chip CHIP0, and forms the second channel CH1. Accordingly, the seventh chip CHIP6 may communicate with the second channel CH1 by the medium of the input/output circuit which is connected with the twelfth through via of the seventh chip CHIP6, and the third chip CHIP2 may communicate with the second channel CH1 by the medium of the input/output circuit 5023 which is connected with the eighth through via 538 of the third chip CHIP2.

The twelfth through via of the sixth chip CHIP5 is connected sequentially with the eleventh through via of the fifth chip CHIP4, the tenth through via of the fourth chip CHIP3, the ninth through via of the third chip CHIP2, the eighth through via 528 of the second chip CHIP1 and the seventh through via 517 of the first chip CHIP0, and forms the third channel CH2. Accordingly, the sixth chip CHIP5 may communicate with the third channel CH2 by the medium of the input/output circuit which is connected with the twelfth through via of the sixth chip CHIP5, and the second chip CHIP1 may communicate with the third channel CH2 by the medium of the input/output circuit 5022 which is connected with the eighth through via 528 of the second chip CHIP1.

The twelfth through via of the fifth chip CHIP4 is connected sequentially with the eleventh through via of the fourth chip CHIP3, the tenth through via of the third chip CHIP2, the ninth through via of the second chip CHIP1 and the eighth through via 518 of the first chip CHIP0, and forms the fourth channel CH3. Accordingly, the fifth chip CHIP4 may communicate with the fourth channel CH3 by the medium of the input/output circuit which is connected with the twelfth through via of the fifth chip CHIP4, and the first chip CHIP0 may communicate with the fourth channel CH3 by the medium of the input/output circuit 5021 which is connected with the eighth through via 518 of the first chip CHIP0.

The input/output circuits 5015, 5016, 5017 and 5018 respectively connected with the fourth through vias 554, 564, 574 and 584 of the fifth to eighth chips CHIP4 to CHIP7 may be is deactivated in response to a first rank select signal, and the input/output circuits respectively connected the twelfth through vias of the first to fourth chips CHIP0 to CHIP3 may be deactivated in response to a second first rank select signal.

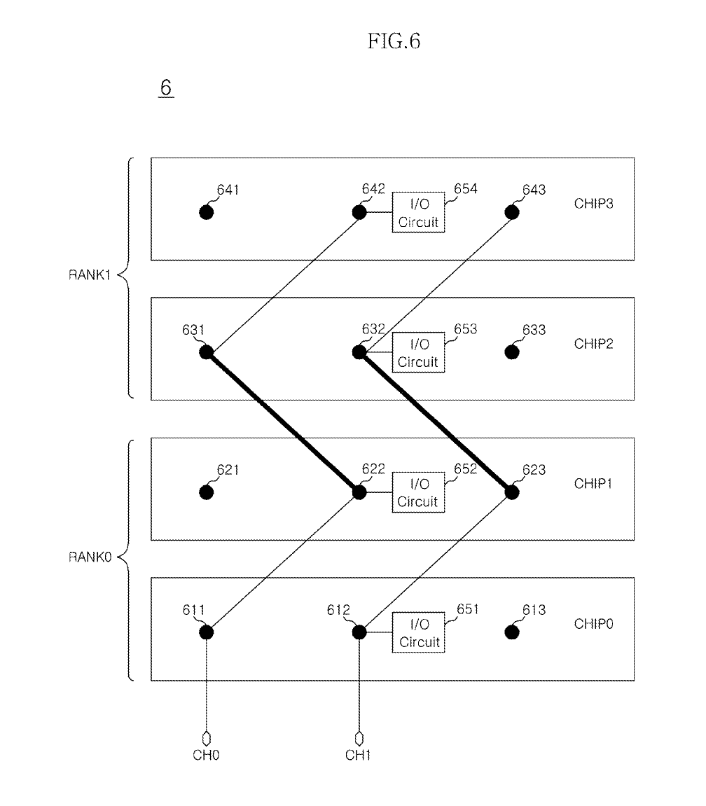

FIG. 6 is a view illustrating the configuration of a semiconductor apparatus 6 in accordance with still another embodiment of the present invention. In FIG. 6, the semiconductor apparatus 6 provides a through via connection scheme that is different from those of the semiconductor apparatuses shown in FIGS. 2 to 5. In FIG. 6, the semiconductor apparatus 6 includes first to fourth chips CHIP0 to CHIP3. The first to fourth chips CHIP0 to CHIP3 are sequentially stacked and constitute the single semiconductor apparatus 6.

The first to fourth chips CHIP0 to CHIP3 include first to third through vias 611 to 613, 621 to 623, 631 to 633 and 641 to 643 which are positioned on the same vertical lines and are formed through the first to fourth chips CHIP0 to CHIP3. The second through vias 612, 622, 632 and 642 of the first to fourth chips CHIP0 to CHIP3 are respectively connected with input/output circuits 651, 652, 653 and 654. The first and second chips CHIP0 and CHIP1 constitute a first rank RANK0, and the third and fourth chips CHIP2 and CHIP3 constitute a second rank RANK1.

The second through via 642 of the fourth chip CHIP3 is connected with the first through via 631 of the third chip CHIP2. The first through via 631 of the third chip CHIP2 is connected sequentially with the second through via 622 of the second chip CHIP1 and the first through via 611 of the first chip CHIP0, and forms a first channel CH0. Accordingly, the fourth chip CHIP3 may communicate with the first channel CH0 by the medium of the input/output circuit 654 which is connected with the second through via 642 of the fourth chip CHIP3, and the second chip CHIP1 may communicate with the first channel CH0 by the medium of the input/output circuit 652 which is connected with the second through via 622 of the second chip CHIP1.

The second through via 632 of the third chip CHIP2 is connected sequentially with the third through via 623 of the second chip CHIP1 and the second through via 612 of the first chip CHIP0, and forms a second channel CH1. Accordingly, the third chip CHIP2 may communicate with the second channel CH1 by the medium of the input/output circuit 653 which is connected with the second through via 632 of the third chip CHIP2, and the first chip CHIP0 may communicate with the second channel CH1 by the medium of the input/output circuit 651 which is connected with the second through via 612 of the first chip CHIP0. The second through via 632 of the third chip CHIP2 may be additionally connected with the third through via 643 of the fourth chip CHIP3.

In the semiconductor apparatus 6 in accordance with the another embodiment of the present invention shown in FIG. 6, even when through vias formed in a plurality of chips are connected in a zigzag pattern and the chips classified into different ranks form a plurality of channels, the number of through vias and the number of input/output circuits may be minimized.

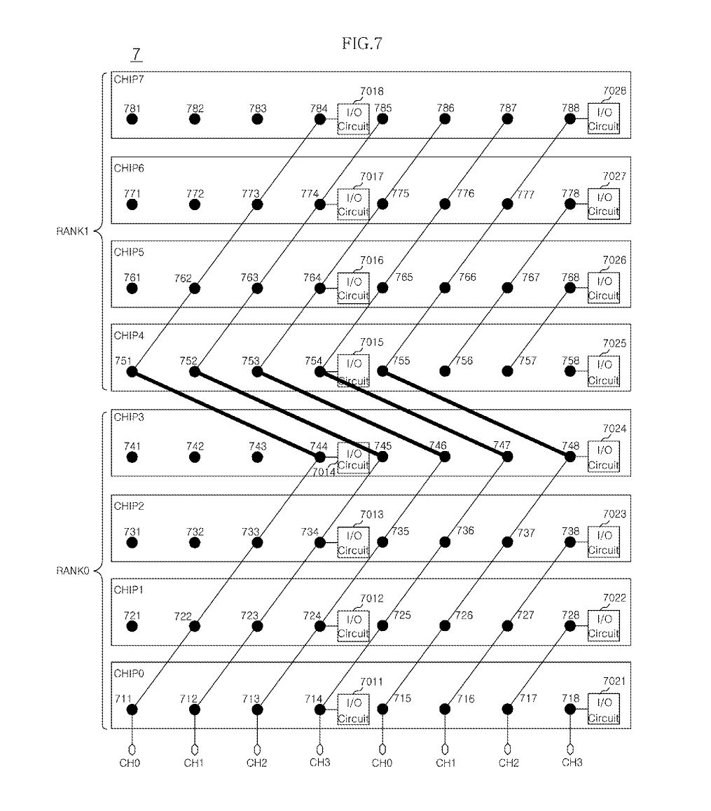

FIG. 7 is a view illustrating the configuration of a semiconductor apparatus 7 in accordance with an embodiment to which the technical concept of the semiconductor apparatus 6 shown in FIG. 6 is applied. In FIG. 7, the semiconductor apparatus 7 includes first to eighth chips CHIP0 to CHIP7. The first to eighth chips CHIP0 to CHIP7 are stacked sequentially and constitute the single semiconductor apparatus 7. The first to eighth chips CHIP0 to CHIP7 include first to eighth through vias 711 to 718, 721 to 728, 731 to 738, 741 to 748, 751 to 758, 761 to 768, 771 to 778 and 781 to 788 which are positioned on the same vertical lines and are formed through the first to eighth chips CHIP0 to CHIP7. The fourth through vias of the first to eighth chips CHIP0 to CHIP7 are respectively connected with input/output circuits 7011, 7012, 7013, 7014, 7015, 7016, 7017 and 7018, and the eighth through vias 718, 728, 738, 748, 758, 768, 778 and 788 of the first to eighth chips CHIP0 to CHIP7 are respectively connected with input/output circuits 7021, 7022, 7023, 7024, 7025, 7026, 7027 and 7028. The first to fourth chips CHIP0 to CHIP3 constitute a first rank RANK0, and the fifth to eighth chips CHIP4 to CHIP7 constitute a second rank RANK1.

The fourth through via 784 of the eighth chip CHIP7 is connected sequentially with the third through via 773 of the seventh chip CHIP6, the second through via 762 of the sixth chip CHIP5 and the first through via 751 of the fifth chip CHIP4. The first through via 751 of the fifth chip CHIP4 is next connected with the fourth through via 744 of the fourth chip CHIP3. Also, the fourth through via 744 of the fourth chip CHIP3 is connected sequentially with the third through via 733 of the third chip CHIP2, the second through via 722 of the second chip CHIP1 and the first through via 711 of the first chip CHIP0, and forms a first channel CH0. Accordingly, the eighth chip CHIP7 may communicate with the first channel CH0 by the medium of the input/output circuit 7018 which is connected with the fourth through via 784 of the eighth chip CHIP7, and the fourth chip CHIP3 may communicate with the first channel CH0 by the medium of the input/output circuit 7014 which is connected with the fourth through via 744 of the fourth chip CHIP3.

The fourth through via 774 of the seventh chip CHIP6 is connected sequentially with the third through via 763 of the sixth chip CHIP5 and the second through via 752 of the fifth chip CHIP4. The second through via 752 of the fifth chip CHIP4 is next connected with the fifth through via 745 of the fourth chip CHIP3. Also, the fifth through via 745 of the fourth chip CHIP3 is connected sequentially with the fourth through via 734 of the third chip CHIP2, the third through via 723 of the second chip CHIP1 and the second through via 712 of the first chip CHIP0, and forms a second channel CH1. Accordingly, the seventh chip CHIP6 may communicate with the second channel CH1 by the medium of the input/output circuit 7017 which is connected with the fourth through via 774 of the seventh chip CHIP6, and the third chip CHIP2 may communicate with the second channel CH1 by the medium of the input/output circuit 7013 which is connected with the fourth through via 734 of the third chip CHIP2. Meanwhile, the fourth through via 774 of the seventh chip CHIP6 may be connected with the fifth through via 785 of the eighth chip CHIP7.

The fourth through via 764 of the sixth chip CHIP5 is connected with the third through via 753 of the fifth chip CHIP4, and the third through via 753 of the fifth chip CHIP4 is connected with the sixth through via 746 of the fourth chip CHIP3. The sixth through via 746 of the fourth chip CHIP3 is connected sequentially with the fifth through via 735 of the third chip CHIP2, the fourth through via 724 of the second chip CHIP1 and the third through via 713 of the first chip CHIP0, and forms a third channel CH2. Accordingly, the sixth chip CHIP5 may communicate with the third channel CH2 by the medium of the input/output circuit 7016 which is connected with the fourth through via 764 of the sixth chip CHIP5, and the second chip CHIP1 may communicate with the third channel CH2 by the medium of the input/output circuit 7012 which is connected with the fourth through via 724 of the second chip CHIP1. Meanwhile, the fourth through via 764 of the sixth chip CHIP5 may be connected sequentially with the fifth through via 775 of the seventh chip CHIP6 and the sixth through via 786 of the eighth chip CHIP7.

The fourth through via 754 of the fifth chip CHIP4 is connected with the seventh through via 747 of the fourth chip CHIP3. The seventh through via 747 of the fourth chip CHIP3 is connected sequentially with the sixth through via 736 of the third chip CHIP2, the fifth through via 725 of the second chip CHIP1 and the fourth through via 714 of the first chip CHIP0, and forms a fourth channel CH3. Accordingly, the fifth chip CHIP4 may communicate with the fourth channel CH3 by the medium of the input/output circuit 7015 which is connected with the fourth through via 754 of the fifth chip CHIP4, and the first chip CHIP0 may communicate with the fourth channel CH3 by the medium of the input/output circuit 7011 which is connected with the fourth through via 714 of the first chip CHIP0.

Similar to the connection structure described above, the eight chip CHIP7 may communicate with the first channel CH0 by the medium of the input/output circuit 7028 which is connected with the eighth through via 788 of the eighth chip CHIP7, and the fourth chip CHIP3 may communicate with the first channel CH0 by the medium of the input/output circuit 7024 which is connected with the eighth through via 748 of the fourth chip CHIP3. The seventh chip CHIP6 may communicate with the second channel CH1 by the medium of the input/output circuit 7027 which is connected with the eighth through via 778 of the seventh chip CHIP6, and the third chip CHIP2 may communicate with the second channel CH1 by the medium of the input/output circuit 7023 which is connected with the eighth through via 738 of the third chip CHIP2. The sixth chip CHIP5 may communicate with the third channel CH2 by the medium of the input/output circuit 7026 which is connected with the eighth through via 768 of the sixth chip CHIP5, and the second chip CHIP1 may communicate with the third channel CH2 by the medium of the input/output circuit 7022 which is connected with the eighth through via 728 of the second chip CHIP1. The fifth chip CHIP4 may communicate with the fourth channel CH3 by the medium of the input/output circuit 7025 which is connected with the eighth through via 758 of the fifth chip CHIP4, and the first chip CHIP0 may communicate with the fourth channel CH3 by the medium of the input/output circuit 7021 which is connected with the eighth through via 718 of the first chip CHIP0.

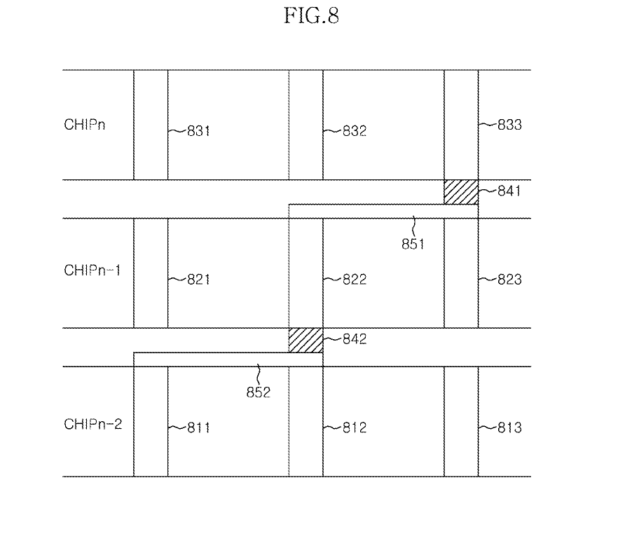

FIG. 8 is a view schematically illustrating a through via connection scheme that may be adopted in the semiconductor apparatus in accordance with an embodiment of the present invention. FIG. 8 illustrates the case in which n−2^{th}, n−1^{th} and n^{th} chips CHIPn−2, CHIPn−1 and CHIPn are stacked. The n−2^{th}, n−1^{th} and n^{th} chips CHIPn−2, CHIPn−1 and CHIPn include first to third through vias 811 to 813, 821 to 823 and 831 to 833 which are positioned on the same vertical lines and are formed through the n−2^{th}, n−1^{th} and n^{th} chips CHIPn−2, CHIPn−1 and CHIPn. In general, in chips including through vias, through vias which are positioned on the same vertical line are electrically connected with one another. In an embodiment of the present invention, through vias which are positioned on different vertical lines may be electrically connected with one another using redistribution layers.

In FIG. 8, the third through via 833 of the n^{th} chip CHIPn is electrically connected with a first redistribution layer 851 through a bump 841. The first redistribution layer 851 extends leftward of the third through via 833 of the n^{th} chip CHIPn and is electrically connected with the second through via 822 of the n−1^{th} chip CHIPn−1. The second through via 822 of the n−1^{th} chip CHIPn−1 is electrically connected with a second redistribution layer 852 through a bump 842. The second redistribution layer 852 extends leftward of the second through via 822 of the n−1^{th} chip CHIPn−1 and is electrically connected with the first through via 811 of the n−2^{th} chip CHIPn−2. Accordingly, by including the first and second redistribution layers 851 and 852, electrical connection paths may be formed from the third through via 833 of the n^{th} chip CHIPn through the second through via 822 of the n−1^{th} chip CHIPn−1 to the first through via 811 of the n−2^{th} chip CHIPn−2. Meanwhile, another metal layer may be disposed between a through via and a bump and/or between a bump and a redistribution layer. Since electrical connections between through vias positioned on different vertical lines may be freely formed in this way, the through via connection scheme in the semiconductor apparatus in accordance with the aforementioned embodiment of the present invention may be easily realized.

While certain embodiments have been described above, it will be understood to those skilled in the art that embodiments described are by way of example only. Accordingly, the semiconductor apparatus described herein should not be limited based on the described embodiments. Rather, the semiconductor apparatus described herein should only be limited in light of the claims that follow when taken in conjunction with the above is description and accompanying drawings.

What is claimed is:

1. A semiconductor apparatus having first and second chips stacked upon each other, comprising:
first, second and third through vias positioned on same vertical lines in the first and second chips and formed through the first and second chips;
a first input/output circuit connected with the second through via of the first chip; and
a second input/output circuit connected with the second through via of the second chip,
wherein the second through via of the second chip is connected with the first through via of the first chip.

2. The semiconductor apparatus according to claim 1, wherein the first through via of the first chip is connected with a first channel, and the second chip communicates with the first channel by the medium of the second input/output circuit.

3. The semiconductor apparatus according to claim 2, wherein the second through via of the first chip is connected with a second channel, and the first chip communicates with the second channel by the medium of the first input/output circuit.

4. A semiconductor apparatus having first to n^{th} chips (n is an integer equal to or greater than 3) stacked upon one another, comprising:
first to m^{th} (m is an integer greater than n) through vias positioned on same vertical lines in the first to n^{th} chips and formed through the first to n^{th} chips; and
input/output circuits respectively connected with n*k^{th} (k is a natural number) through vias of the first to n^{th} chips,
wherein the n^{th} through via of the n^{th} chip is connected with the n−1^{th} through via of the n−1^{th} chip, and the n^{th} through via of the n−1^{th} chip is connected with the n+1^{th} through via of the n^{th} chip and the n−1^{th} through via of the n−2^{th} chip.

5. The semiconductor apparatus according to claim 4, wherein the first to n^{th} chips communicate through respective is independent channels.

6. A semiconductor apparatus having first, second, third and fourth chips sequentially stacked upon one another, the first and second chips constituting a first rank and the third and fourth chips constituting a second rank, comprising:
first, second, third and fourth through vias positioned on the same vertical lines in the first, second, third and fourth chips and formed through the first, second, third and fourth chips;
input/output circuits connected with the second through vias of the first, second, third and fourth chips; and
input/output circuits connected with the fourth through vias of the first, second, third and fourth chips,
wherein the fourth through via of the fourth chip is connected sequentially with the third through via of the third chip, the second through via of the second chip and the first through via of the first chip, and forms a first channel.

7. The semiconductor apparatus according to claim 6, wherein the fourth chip communicates with the first channel by the medium of the input/output circuit which is connected with the fourth through via of the fourth chip, and the second chip communicates with the first channel by the medium of the input/output circuit which is connected with the second through via of the second chip.

8. The semiconductor apparatus according to claim 7, wherein the fourth through via of the third chip is connected sequentially with the third through via of the second chip and the second through via of the first chip, and forms a second channel.

9. The semiconductor apparatus according to claim 8, wherein the third chip communicates with the second channel by the medium of the input/output circuit which is connected with the fourth through via of the third chip, and the first chip communicates with the second channel by the medium of the input/output circuit which is connected with the second through via of the first chip.

10. The semiconductor apparatus according to claim 9, wherein the fourth through via of the second chip is connected with the third through via of the first chip, and forms the first channel.

11. The semiconductor apparatus according to claim 10, wherein the second chip communicates with the first channel by the medium of the input/output circuit which is connected with the fourth through via of the second chip.

12. The semiconductor apparatus according to claim 11, wherein the fourth through via of the first chip forms the second channel.

13. The semiconductor apparatus according to claim 12, wherein the first chip communicates with the second channel by the medium of the input/output circuit which is connected with the fourth through via of the first chip.

14. The semiconductor apparatus according to claim 13, further comprising:
fifth and sixth through vias positioned on the same vertical lines in the first, second, third and fourth chips and formed through the first, second, third and fourth chips; and
input/output circuits connected with the sixth through vias of the first, second, third and fourth chips,
wherein the sixth through via of the fourth chip is connected sequentially with the fifth through via of the third chip and the fourth through via of the second chip.

15. The semiconductor apparatus according to claim 14, wherein the sixth through via of the third chip is connected sequentially with the fifth through via of the second chip and the fourth through via of the first chip.

16. The semiconductor apparatus according to claim 14, wherein the input/output circuits connected with the sixth through vias of the first and second chips are deactivated in response to a second rank select signal for activating the second rank.

17. The semiconductor apparatus according to claim 6, wherein the input/output circuits connected with the second through vias of the third and fourth chips are deactivated in response to a first rank select signal for activating the first rank.

18. A semiconductor apparatus having first, second, third and fourth chips sequentially stacked upon one another, the first and second chips constituting a first rank and the third and fourth chips constituting a second rank, comprising:
first, second and third through vias positioned on the same vertical lines in the first, second, third and fourth chips and formed through the first, second, third and fourth chips; and
input/output circuits connected with the second through vias of the first, second, third and fourth chips,
wherein the second through via of the fourth chip is connected sequentially with the first through via of the third chip, the second through via of the second chip and the first through via of the first chip, and forms a first channel.

19. The semiconductor apparatus according to claim 18, wherein the fourth chip communicates with the first channel by the medium of the second through via of the fourth chip, and the second chip communicates with the first channel by the medium of the second through via of the second chip.

20. The semiconductor apparatus according to claim 18, wherein the third through via of the fourth chip is connected sequentially with the second through via of the third chip, the third through via of the second chip and the second through via of the first chip, and forms a second channel.

21. The semiconductor apparatus according to claim 20, wherein the third chip communicates with the second channel by the medium of the input/output circuit which is connected with the second through via of the third chip, and the first chip communicates with the second channel by the medium of the input/output circuit which is connected with the second through via of the first chip.
